(19) United States
(12) Patent Application Publication
(10) Pub. No.: US 2003/0085050 A1
(43) Pub. Date: May 8, 2003

(54) EMI air filter

(75) Inventors: John C. Zarganis, Redwood City, CA (US); Rocky R. Arnold, San Carlos, CA (US); John F. Gabower, Mauston, WI (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Shielding for Electronics, Inc., Sunnyvale, CA

(21) Appl. No.: 10/230,966

(22) Filed: Aug. 28, 2002

Related U.S. Application Data
(60) Provisional application No. 60/316,822, filed on Sep. 4, 2001.
(60) Provisional application No. 60/339,237, filed on Dec. 13, 2001.

(51) Int. Cl. H05K 9/00

(52) U.S. Cl. 174/35 MS

(57) ABSTRACT

The present invention provides electromagnetic interference filters and gaskets. In exemplary embodiments, the filters and gaskets are made from conductively coated reticulated foam having a pore density varying from 10 to 40 pores per inch (PPI). The filters can be used to cover ventilation openings in an electronics enclosure to shield electrical components, equipment and devices from EMI, electrostatic discharge (ESD) and radio frequency interference (RFI) while still providing adequate airflow to enter and cool the system. The filter material may also help prevent dust and dirt from entering the enclosure. The filters of the present invention are also well suited to conductively bridge gaps between mating features of electronic enclosures. The reticulated foam to fabricate the filters allow for excellent compression (generally 20%-50% of the original thickness) under low compressive forces, while easily recovering from the compressive load without noticeable compression set (permanent deflection).

### CROSS-REFERENCES TO RELATED APPLICATIONS

The present application claims benefit, under 37 C.F.R. § 1.78, to U.S. Provisional Patent Application No. 60/316,822 filed Sep. 4, 2001, and entitled “EMI Gasketing Material Using Conductive Coating” and U.S. Provisional Patent Application No. 60/339,237, filed Dec. 13, 2001, and entitled “EMI Gasketing Material Using Conductive Coatings on Reticulated Foam in Combination with Metalized Plastic Layers,” the complete disclosures of which are incorporated herein by reference.

### BACKGROUND OF THE INVENTION

EMI filters are commonly found in personal computers, networking equipment, cellular telephones, and other similar electronic devices. These EMI filters can further act as a conductive grounding interface between mating features of enclosures used to house a printed circuit board (PCB) or similar devices. This is desirable since electronic components commonly found on PCB's, or similar devices, both emit, and are susceptible to electromagnetic interference (EMI), electrostatic discharge (ESD), and radiofrequency interference (RFI). The proper design of an electronic system and corresponding enclosure will both minimize system emissions as well as protect the system from outside noise created by external devices allowing all devices in close proximity to one another to function as intended.

A properly designed electronic enclosure is commonly achieved by providing a continuous conductive barrier around an electronic system thereby creating what is known as a “Faraday Cage.” The Faraday Cage principle is the concept that a continuous, conductive enclosure will either reflect incident radiation or transmit electrical interference to ground, rendering the emissions less troublesome.

One of the ways such an enclosure is reduced in effectiveness is from required apertures for ventilation or from inadvertent gaps from the fabrication process that occur between the mating surfaces of the metalized parts that form the enclosure. These apertures and gaps can reduce the shielding effectiveness of an enclosure by creating openings that allow radiant energy to pass through or enter the system. These gaps or openings can even intensify EMI radiation by acting as a slot antenna that can help to radiate emissions. Additionally, these gaps are a source of ground discontinuity, thereby reducing the EMI reflection and absorption capabilities of the enclosure.

To solve such EMI/RFI problems, several products have been proposed. U.S. Pat. No. 6,384,325 proposes the use honeycomb like structures as a waveguide to prevent EMI from passing into and out of an enclosure. Some other proposed gasketing solutions used between mating enclosure features utilize a resilient core in a variety of shapes and sizes coated by a conductive wire mesh or sheath (U.S. Pat. No. 5,902,956). Also commonly used is a “form in place” gasket consisting mainly of an elastomer resin filled with conductive fillers (U.S. Pat. Nos. 6,096,413 and 5,641,438).

While the methods listed above are relatively effective, they all have various disadvantages. Honeycomb EMI filters are generally very thick dimensionally and are neither compressible nor recoverable under compressive loads. In addition, such honeycomb filters are relatively heavy. With today's electronics enclosures becoming constantly smaller and lighter, a bulky EMI filter that is unable to conform to complex shapes limits the number of applications where these types of filters would be suitable.

Sheathed resilient core EMI gaskets are typically formed in a linear fashion from a non-conductive foamed elastomer thermoplastic such as a polyethylene, polypropylene, butadiene, styrene-butadiene, or similar materials. These resilient cores can be either formed or molded inside a conductive mesh or sheath. Alternatively, the cores can be wrapped after the molding or forming process in a similar type of mesh, sheath or foil. Occasionally, adhesives are introduced to act as a bonding agent between the core and the mesh. The mesh or sheath can typically be made entirely from common metals such as copper, aluminum, tin, gold, silver, nickel or similar alloys. In addition, a composite fiber mesh or sheath can be made by coating or plating synthetic fibers such as nylon, polyester, polyethylene, cotton, wool or the like in common conductive metals.

This type of linear gasket does have its limitations with mechanically and electrically securing the gasket when used in enclosures with irregular or non-linear contours. In order to match an irregular contour of an enclosure or boundary interface to be sealed, such linear gaskets are often sectioned in an effort to facilitate securing the gasket to the enclosure. Sectioning or cutting the sheathed gasket has adverse effects. Typically when cut, the ends of the mesh or sheath portion of the gasket have a tendency to fray or unravel thereby compromising the conductivity of the gasket and possibly depositing flakes or bits of conductive material into the system introducing the possibility of electrically shorting the system. When adhesives are used, the adhesive will have a tendency to coat the conductive mesh fibers with non-conductive adhesives. This often reduces the mesh fibers' shielding effectiveness by insulating their conductive properties causing grounding discontinuities.

Form in place gaskets are typically comprised of a foamed, gelled or unfoamed elastomer resin(s), such as silicone urethane or other similar polymers and are used as a carrier for conductive fillers. The filled resin is lined onto one or more mating surfaces of an enclosure to provide an EMI shielding gasket. Alternatively, an unfilled elastomer resin can be lined onto the enclosure and then coated with a conductive outer layer, such as silver, or other similar alloy. While these types of gaskets are quite common and can be applied with the proper machinery to most contours and mating surface patterns, they do have some disadvantages. Form in place gaskets are only partially filled with conductive materials and are not 100% conductive material. Therefore, these gaskets typically require high compressive forces between the mating enclosure surfaces to ensure that adequate grounding contact is made with the conductive particles contained within the elastomer resin. With today's electronic enclosures becoming both smaller and being designed with increasingly thinner wall thickness, achieving the necessary compressive forces without flexing or damaging the enclosure becomes more difficult. Additionally, with the inclusion of conductive particles, the elastic compressions recovery properties of the elastomer resin can be diminished, thereby reducing the ability to open and close the enclosure if access to the internal electronics is necessary for rework or maintenance.

In an attempt to solve some of the drawbacks of the aforementioned methods, U.S. Pat. No. 6,309,742 to Clupper et al. proposes the use of a metalized reticulated and elastomeric foam that has a pore density in the 80-240 PPI range. Clupper et al. cites an improved rigidity, resiliency to compression set, and improved electrical conductivity as justification for utilizing a high pore density material.

However, the high foam pore density has been found to decrease the shielding effectiveness of the EMI shield. This is most likely attributed to the higher pore density preventing the filter from being metalized completely throughout the entire thickness of foam. As a result the filter has poor three dimensional or “XYZ” universal conductivity throughout the thickness. As such, the EMI shield has the tendency to be only conductive on the outside surfaces and not in the center. Thus, any post-processing (die cutting, shearing etc.) done to metalized high-density reticulated foam would further expose the unmetalized internal areas and potentially reduce the shielding effectiveness even further.

For the above reasons, what is needed are improved methods and EMI filters.

### BRIEF SUMMARY OF THE INVENTION

The methods of the present invention provide improved EMI/RFI air filters and gaskets. The present invention avoids the disadvantages of the prior art by creating a conductive EMI/RFI air filter from a compressible, reticulated foam or a similar elastomer material that is completely metalized throughout the entire filter thickness.

In one aspect, the present invention provides an EMI/RFI air filter. The EMI/RFI filter comprises a substrate having an open-cell skeletal structure and a pore density between approximately 10 pores per inch and 40 pores per inch. A conductive metal coating can be deposited on the substrate throughout the open-cell skeletal structure of the substrate so as to maintain electrical continuity throughout the substrate.

In exemplary EMI/RFI air filters of the present invention, the elastomer substrate (e.g., reticulated urethane foam, polyethylene, polypropylene, polyvinyl chloride, ether-type polyurethane, polyamide, polybutadiene, silicone, or similar elastomer materials) is metalized without the use of any intermediate or adhesive-promoting steps. In other EMI filters of the present invention, however, various intermediate steps can be introduced to provide an adhesion-promoting layer to a substrate prior to the metalization.

The metal coating over the entire open cell structure provides continuous conductivity throughout the filter and can provide attenuation of at least 50 dB over frequency range of 100 MHz and 1 GHz. Typically the attenuation range is between 50 dB and 90 dB.

In another aspect, the present invention provides a method of filtering air and EMI/RFI. The method comprises providing an open-celled substrate comprising a skeletal structure that has a pore density between approximately 10 pores per inch and 40 pores per inch. A conductive metal coating is deposited throughout the open celled skeletal structure. The metalized substrate is placed adjacent a ventilation aperture to filter debris from an airflow and to filter EMI/RFI.

In a further aspect, the present invention provides a conductive EMI/RFI gasket. The gasket comprises a compressible substrate having an open-cell skeletal structure and a pore density between approximately 10 pores per inch and 40 pores per inch. A conductive metal coating is deposited throughout the open-cell skeletal structure of the substrate such that the conductive metal coating maintains electrical continuity throughout the substrate when under a compression force.

The EMI gaskets of the present invention can conductively bridge gaps between mating features of an electronic enclosure. The reticulated foam and elastomer materials used to fabricate the gaskets allow for excellent deflection (generally 20%-50% of the original thickness) under low compressive forces, while easily recovering from the compressive load without noticeable compression set (permanent deflection).

Because of the continuous conductivity throughout the open-cell structure, the EMI/RFI air filters can be die cut (before or after metalization) so as to conform to the gaps between two bodies.

In yet another aspect, the present invention provides a method of EMI/RFI shielding. The method comprises providing a compressible, open-celled substrate comprising a skeletal structure that has a pore density between approximately 10 pores per inch and 40 pores per inch. A conductive metal coating is deposited throughout the open celled skeletal structure so as to provide a continuous conductivity throughout the substrate. The metalized substrate can then be placed between two bodies to seal a gap between mating features of the two bodies.

A further understanding of the nature and advantages of the invention will become apparent by reference to the remaining portions of the specification and drawings.

### BRIEF DESCRIPTION OF THE DRAWINGS

FIG. 1 illustrates a reticulated elastomer foam substrate and a metalized reticulated elastomer foam substrate of the present invention;

FIG. 2 is a perspective view of a metalized reticulated foam having a porosity of 40 PPI (left) and a metalized reticulated foam with a porosity of 10 PPI (right);

FIG. 3 illustrates an example of an application where the metalized filter can be used to cover ventilation apertures of an enclosure door;

FIG. 4 illustrates an example of an application where the metalized filter can be used to bridge a gap between mating surfaces of an enclosure door and an enclosure chassis;

FIGS. 5A and 5B are graphs of shielding effectiveness data generated from tests of the exemplary EMI/RFI air filter and an EMI/RFI gasket of the present invention, respectively; and

FIG. 6 is a graph of airflow properties of the present invention.

### DETAILED DESCRIPTION OF THE INVENTION

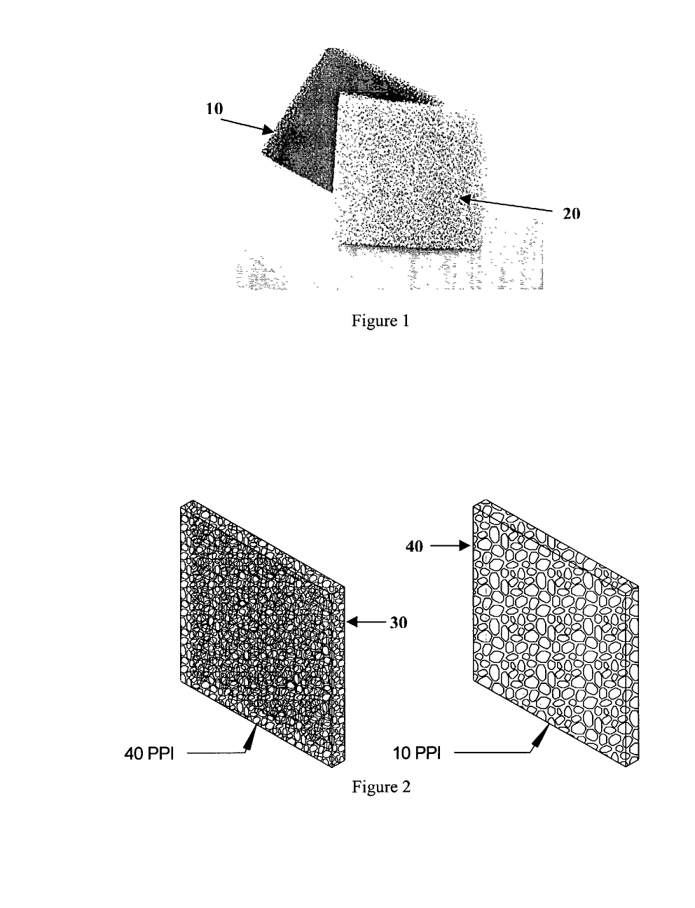

FIG. 1 illustrates a foam substrate 10 (before metalization) and a metalized foam substrate 20. The foam substrates 10 of the present invention can be a reticulated foam or other similar materials that have an open-cell, skeletal structures. Some exemplary materials that can be used as the substrate include, but is not limited to, reticulated polyurethane, polyethylene, polypropylene, polyvinyl chloride, ether-type polyurethane, polyamide, polybutadiene, or silicone.

The foam substrates can be formulated in a wide variety of porosities (rated by the number of pores per inch (PPI)). In the present invention, the porosity of the foam substrate will typically vary between 10 PPI and 60 PPI, and preferably between approximately 10 PPI and 40 PPI. It should be appreciated, however, that the present invention is not limited to such porosity ranges, and the present invention can utilize foam substrates having a lower or higher porosity. FIG. 2 is a visual representation of a metalized reticulated foam substrate 30 with a porosity of 40 PPI and a reticulated foam substrate 40 having a porosity of 10 PPI.

The process of metalizing the foam substrate 10 material can be performed through a variety of techniques including, but not limited to vacuum deposition, thermal vapor deposition, electroless plating, sputtering etc. The metal coatings will generally be composed of Aluminum, Nickel-Chromium and/or other similar alloys. It should be appreciated, however, that other conductive metals, such as copper, nickel, tin, gold, silver, cobalt and other metals may be deposited onto the substrate, if desired.

In exemplary embodiments the metal coating is deposited throughout the entire three-dimensional or XYZ thickness of the substrate so as to coat substantially the entire lattice of the open-cell structure of the foam substrate 10. The metal coating will preferably be deposited in thin layers over the entire lattice of the substrate in layers that are between approximately 1 micron to 50 microns (micrometers) thick.

In other embodiments, however, instead of metalizing throughout the entire XYZ thickness of the substrate, it may be possible to metalize only the outer surfaces of the substrate or only an inner or outer portion of the substrate.

It should be noted, that some of the elastomer substrates used in this invention, while under vacuum, might outgas sufficiently enough to interfere with the metalization process. For this situation, prior to depositing the metal layer, the substrate may be coated with an intrinsically conductive polymer (ICP) to reduce outgassing so that sufficient metalization can take place.

FIG. 2 shows the variation in the size of pores that occurs between samples with a pore size of 10 PPI and a sample of 40 PPI. The thickness of foam that can be completely metalized is largely dependent on the porosity of the foam substrate. A substrate with fewer pores per inch will generally contain larger pores. Larger pores create larger openings for the metal particles to pass through and allows for coating a greater thickness of foam. The greater thickness provides a more robust air filter that can provide better EMI/RFI shielding.

The substrate having a porosity between approximately 10 PPI and 40 PPI will generally have a thickness between approximately 0.500 inches and 0.125 inches. Conversely, a sample with higher number of pores per inch (greater than 40 PPI) contains smaller pores thereby limiting the ability of the metal particles to penetrate the foam and reducing the material thickness that can be successfully coated throughout.

To improve the metalization of the center of the substrate, the substrate may be mechanically stretched during the metalization so that the pores are elongated allowing for the metallic material to be more easily deposited into and throughout a greater thickness of foam. In addition, to improve the XYZ conductivity in higher porosity materials, a conductive base foam material (from an earlier process such as particulate loading with graphite, nickel flakes or particles) may be used.

The filters of the present invention can be easily fabricated into a desired shape by die-cutting, shearing, or other similar techniques either before or after metalization. This flexibility makes this invention well suited for covering openings in enclosures and for sealing gaps along mating surfaces of electronic enclosures.

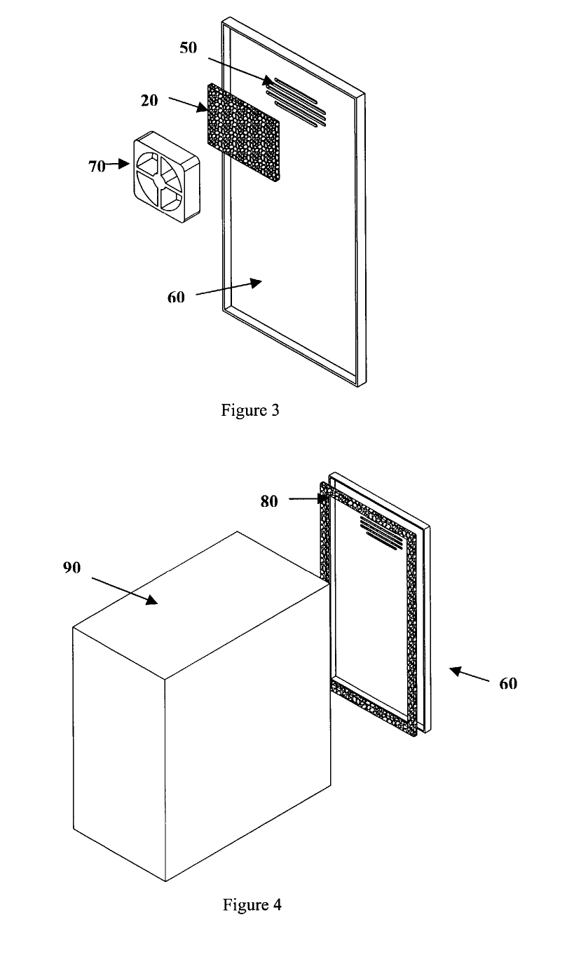

FIG. 3 depicts an example where the filter 20 of the present invention can be used to cover necessary ventilation apertures 50 that are commonly found on an electronic enclosures door 60. A ventilation fan 70 or other ventilation device could then be placed over the filter to pull or push air into or out of an electronic enclosure through the filter. The foam substrate with the conductive coating are particularly suited for EMI and RFI filtering and enclosure sealing purposes, as well as filtering potentially harmful debris from the air entering and exiting the electronic enclosure. In such applications, if the air filter 20 is too thin, the continuous air flow through the air filter may detrimentally affect the integrity of the air filter and create gaps which may act as slot antennas for EMI/RFI.

In addition to using the metalized foam substrate as an EMI/RFI air filter 20, the present invention can be used as an EMI gasket 80. FIG. 4 depicts an example of how the devices of the present invention can be used to seal a gap between mating features of an enclosure. The metalized gasket can be cut (before or after metalization) to fit the inside edges of an enclosure door 60. A chassis body 90 can then press against the filter 80 upon closure of the door 60. The closure force would compress the filter 80 allowing it to conform to any uneven surfaces that may be present at either mating surface and provide a reliable and conductive EMI seal between the two surfaces. The reticulated foam allow for excellent compression under low compressive forces, while easily recovering from the compressive load without noticeable compression set (permanent deflection) or separation of the layers of the filter. It is generally desirable that the filter or gasket be compressed between 20% and 50% of the original foam thickness while in use in order to ensure good electrical grounding contact between mating surfaces. The load requirement for compressing the foam should be less than 50 pounds per square inch (psi.).

In one exemplary embodiment, the EMI/RFI air filters and EMI/RFI gaskets of the present invention are comprised of reticulated polyurethane foam that is metalized with a vacuum metalization process. Applicants have found that such a combination does not require any intermediate steps to adhere the metal coating to the lattice of the reticulated foam. The final EMI/RFI air filter 20 and gasket 80 can therefore be made faster and more economically while still providing good adhesion between the substrate and metal layer. A more complete description of a preferred vacuum metalization process is described in commonly owned U.S. Pat. No. 5,811,050 to Gabower et al.

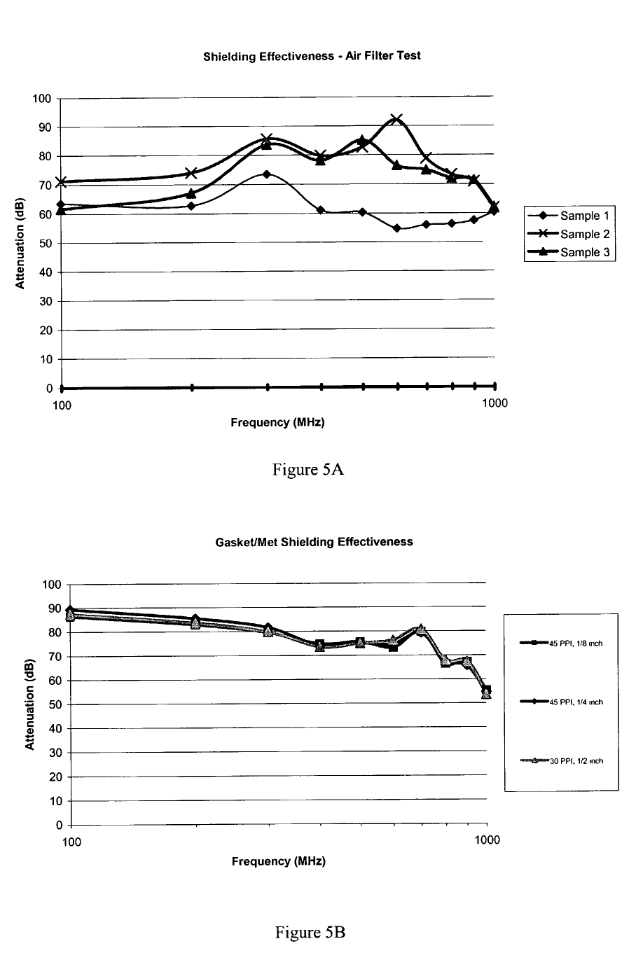

FIGS. 5A and 5B are graphical representations of EMI tests that were performed on EMI air filters and EMI gaskets of the present invention. All tests were performed at an accredited EMC test facility according to MIL-STD-285 shielding effectiveness test. The Y-axis shows the shielding effectiveness, rated in decibels of attenuation (dB) level the various samples provided over a varying frequency range (X-axis) measured in Mega Hertz (1×10⁶ Hz). Additionally, due to the small and randomized spacing of the open cell pores and lattices of the reticulated foams, airflow is allowed to convect through these materials for ventilation purposes while at the same time inhibiting EMI, dust and dirt particles from passing through. As shown in FIG. 5A, the tested samples were tested between 100 Mhz and 1 Ghz, and the samples provided EMI attenuation between approximately 50 dB and 90 dB. FIG. 5B illustrates the EMI shielding effectiveness of a compressed EMI gasket for various PPI and thicknesses.

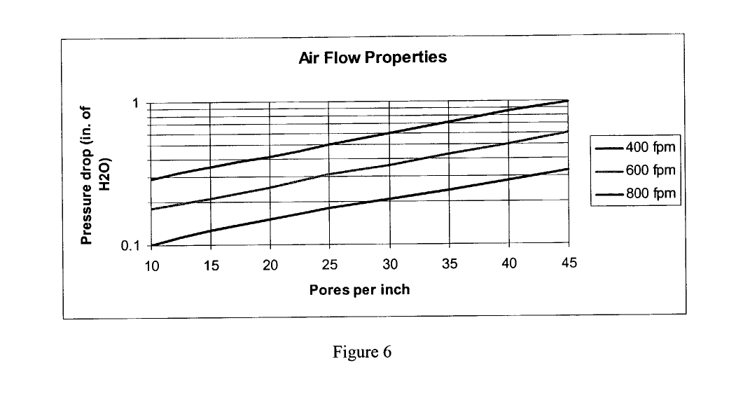

FIG. 6 is a chart that graphically depicts the ventilation properties of the EMI air filters over various porosity ranges. The Y-axis represents the airflow reduction (rated in inches of H₂O) as air at different flow rates (rated in feet per minute) passes through the samples of various pore sizes. The pore size variety (rated in PPI) can be found on the X-axis. As shown in FIG. 6, the airflow properties of the metalized filters 20 vary linearly with pores per inch. As the pores per inch in the substrate increases, a greater air flow is allowed to pass through the air filter, which improves cooling effects of the filter. A more complete description of the ventilation properties of foam substrates can be found at http://www.foamex.com/foamex.htm.

While this invention has been described in terms of several preferred embodiments, it is contemplated that alterations, permutations and equivalents thereof will become apparent to those skilled in the art upon a reading of the specification and study of the drawings.

What is claimed is:

1. An EMI/RFI air filter comprising:
a substrate having an open-cell skeletal structure and a pore density between approximately 10 pores per inch and 40 pores per inch; and
a conductive metal coating deposited on the substrate throughout the open-cell skeletal structure of the substrate so as to maintain electrical continuity throughout the substrate.

2. The EMI/RFI filter of claim 1 wherein the metal coating comprises a thickness of between approximately 1 micron and 50 microns on the skeletal structure of the substrate.

3. The EMI/RFI air filter of claim 1 wherein the substrate comprises a reticulated foam.

4. The EMI/RFI air filter of claim 1 wherein the substrate comprises polyethylene, polypropylene, polyvinyl chloride, ether-type polyurethane, polyamide, polybutadiene, or silicone.

5. The EMI/RFI air filter of claim 1 wherein the metal coating comprises Aluminum, Nickel-Chromium and their alloys.

6. The EMI/RFI air filter of claim 1 wherein the substrate is able to compress by 20% to 50% of the original filter thickness without losing electrical continuity of the metal coating.

7. The EMI/RFI air filter of claim 1 wherein the substrate has a thickness between approximately 0.125 and 0.500 inches thick.

8. The EMI/RFI air filter of claim 1 comprising an intrinsically conductive polymer coating between the substrate and the metal coating, wherein the polymer coating reduces outgassing of the substrate during metalization.

9. The EMI/RFI air filter of claim 1 wherein the EMI air filter provides a shielding effectiveness of at least 50 dB.

10. A method of filtering air and EMI/RFI, the method comprising:
providing an open-celled substrate comprising a skeletal structure that has a pore density between approximately 10 pores per inch and 40 pores per inch;
depositing a conductive metal coating throughout the open celled skeletal structure; and
placing the metalized substrate adjacent a ventilation aperture to filter debris from an airflow and to filter EMI/RFI.

11. The method of claim 10 comprising stretching the substrate prior to depositing the metal coating on the substrate.

12. The method of claim 10 comprising grounding the metalized substrate with a housing of the ventilation aperture.

13. The method of claim 10 wherein depositing the metal coating is carried out with vacuum metalization.

14. The method of claim 10 wherein the metalized substrate has a shielding effectiveness of at least 50 dB.

15. The method of claim 10 comprising reducing outgassing of the substrate by depositing an intrinsically conductive polymer coating on the substrate prior to depositing the metal coating.

16. A conductive EMI/RFI gasket comprising:
a compressible substrate having an open-cell skeletal structure and a pore density between approximately 10 pores per inch and 40 pores per inch; and
a conductive metal coating deposited throughout the open-cell skeletal structure of the substrate, wherein the conductive metal coating maintains electrical continuity throughout the substrate when under a compression force.

17. The EMI/RFI gasket of claim 16 wherein the metal layer is comprised of Aluminum, Nickel-Chromium or their alloys and the metal layer has a thickness between approximately 1 micron and 50 microns.

18. The EMI/RFI gasket of claim 16 wherein the compressible substrate is comprised of a reticulated foam.

19. The EMI/RFI gasket of claim 16 wherein the substrate comprises polyethylene, polypropylene, polyvinyl chloride, ether-type polyurethane, polyamide, polybutadiene, or silicone.

20. The EMI/RFI gasket of claim 16 wherein the substrate is able to compress by 20% to 50% of the original filter thickness without losing electrical continuity of the metal coating.

21. The EMI/RFI gasket of claim 16 wherein the gasket provides a shielding effectiveness of at least 50 dB.

22. A method of EMI/RFI shielding comprising:
providing a compressible, open-celled substrate comprising a skeletal structure that has a pore density between approximately 10 pores per inch and 40 pores per inch;
depositing a conductive metal coating throughout the open celled skeletal structure so as to provide a continuous conductivity throughout the substrate; and
placing the metalized substrate between two bodies to seal a gap between mating features of the two bodies.

23. The method of claim 22 comprising compressing the metalized substrate between the two bodies, wherein the compressed metalized substrate maintains electrical conductivity throughout a cross-section of the substrate under compression.

24. The method of claim 23 wherein compressing the metalized substrate comprises allowing the metalized substrate to conform to a surface of the two bodies.

25. The method of claim 22 wherein the gasket provides a shielding effectiveness of at least 50 dB.
